(19) United States
(12) Patent Application Publication
(10) Pub. No.: US 2011/0318886 A1
(43) Pub. Date: Dec. 29, 2011

(54) METHOD FOR FORMING CIRCUIT PATTERNS ON SURFACE OF SUBSTRATE

(75) Inventor: LUNG-CHUAN TSAO, Guiren Shiang (TW)

(73) Assignee: NATIONAL PINGTUNG UNIVERSITY OF SCIENCE & TECHNOLOGY, Neipu Hsiang (TW)

(21) Appl. No.: 13/163,660

(22) Filed: Jun. 17, 2011

(30) Foreign Application Priority Data
Jun. 29, 2010 (TW) 099121323

(51) Int. Cl. H01L 21/50

(52) U.S. Cl. 438/125; 257/E21.499

(57) ABSTRACT

A method for forming circuit patterns on a surface of a substrate is provided and has steps of: providing and pre-heating a substrate having an insulation surface on one side thereof; providing an activation connection device for oscillating and painting an activation solder onto the pre-heated insulation surface to heat and melt the activation solder; applying ultrasonic waves to the melted activation solder by the activation connection device, so as to activate the activation solder and the insulation surface by the ultrasonic waves; and moving the activation connection device, so as to form a circuit pattern on the insulation surface by the activation solder.

### FIELD OF THE INVENTION

The present invention relates to a method for forming circuit patterns on a surface of a substrate, and more particularly to a method for forming circuit patterns on a surface of a substrate, which uses steps of pre-heating an insulation surface of the substrate and activating the insulation surface of the substrate by ultrasonic waves to directly connect an activation solder onto the insulation surface for forming the circuit patterns.

### BACKGROUND OF THE INVENTION

Recently, with the development of technologies and the trends of precision, compactness and miniaturization of electronic products, it becomes important to maintain the operational stability of products, wherein the power conversion and operation of an electronic product generally generates a large amount of heat which is an important factor affecting the stability. If internal components of the product are over-heated, it may seriously and permanently damage the product. To solve the foregoing problem, heat-generating components of many electronic products are installed with a heat-dissipation substrate.

For example, in a backlight module of a traditional liquid crystal display (LCD), there is a trend to use light emitting diodes (LEDs) as backlight sources of the backlight module, wherein a plurality of LEDs are mounted on a heat-dissipation substrate to form a light bar, and a backlight module is generally constructed by a plurality of light bars. For simplifying the installation structure of the light bar, a surface of the heat-dissipation substrate is directly formed with a surface circuit layer for directly mounting the LEDs, while the LEDs can obtain the electric power from the surface circuit layer, so as to emit light beam.

For example, Taiwan Utility Model Patent No. M373629, entitled “PACKAGE STRUCTURE OF ELECTRONIC DEVICE AND CIRCUIT BOARD THEREOF”, discloses a metal or ceramic substrate which is stacked with a heat-dissipation adhesive layer, a third glue layer, a first metal layer, a first glue layer, a second metal layer and a second glue layer in turn, wherein the first glue layer exposes a portion of the first metal layer to form a first contact pad for being thermally connected to leads of an LED, so that heat from the leads of the LED can be transferred to the substrate through the first metal layer and the heat-dissipation adhesive layer for dissipating the heat. Furthermore, the second glue layer exposes a portion of the second metal layer to form a second contact pad for being electrically connected to other leads of an LED, so that these leads of the LED can be electrically connected to an external power through the second metal layer.

Nowadays, for enhancing the illumination efficiency and the light uniformity, the total number and output power of the LEDs mounted on the heat-dissipation substrate are gradually increased day by day. However, during the LEDs convert the electric power into the light, the large number of the LEDs generates considerable waste heat, so as to generate relatively high operational temperature. Thus, the LED Chip will be break down at the higher working temperature. Another, because the connection strength of the surface circuit layer of the heat-dissipation substrate is low and the heat resistance thereof is poor, the surface circuit layer will be easily peeled off or damaged due to thermal expansion and contraction or adhesive lose of material deterioration, resulting in considerably lowering the life time of the electronic products (such as the backlight module) having the heat-dissipation substrate. The Taiwan Utility Model Patent No. M373629 is exemplified. During installation, the heat-dissipation adhesive layer is firstly printed on the heat-dissipation substrate, and then the metal layer is adhered thereon by heating. However, the heating operation of the installation may cause the oxidation of the metal layer, resulting in affecting the adhesion strength and the heat dissipation effect. Moreover, under the normal operational condition, the LEDs frequently generate high temperature in a long time, so that the heat-dissipation adhesive layer made of silver adhesive or other adhesive material and the glue layer made of polyimide (Pl) may be easily heated and deteriorated. Especially, the portion of the heat-dissipation adhesive layer may be easily peeled off. When the surface circuit layer is separate from the heat-dissipation substrate, the waste heat of the LEDs can not be dissipated outward in time, and thus the LEDs may be burned and damaged.

As a result, it is necessary to provide an improved method for forming circuit patterns on a surface of a substrate to solve the problems existing in the conventional technologies, as described above.

### SUMMARY OF THE INVENTION

A primary object of the present invention is to provide a method for forming circuit patterns on a surface of a substrate, which firstly pre-heats an insulation surface of a substrate; then directly heats and connects a melted activation solder onto the insulation surface after oscillating and painting the activation solder on the insulation surface; and activates the insulation surface and the activation solder by ultrasonic waves, wherein the ultrasonic waves can break the surface oxidation film of the activation solder, while the energy of the ultrasonic waves can efficiently remove surface dirt and a passivation layer on the insulation surface through particles of extremely hard intermetallic compounds (IMGs) of the activation solder, in order to carry out the dual activation effect of activating the activation solder and the insulation surface. Thus, the present invention can relatively increase the connection property of wetting and connecting the activation solder onto the insulation surface, and thus it is advantageous to enhance the connection strength and process efficiency of the circuit patterns.

A secondary object of the present invention is to provide a method for forming circuit patterns on a surface of a substrate, wherein a multi-axis motion device is used to rapidly execute the foregoing steps on the insulation surface of a planar substrate or 3-dimensional substrate to form the circuit patterns, and the ultrasonic waves are used to oscillate to break the oxidation surface film of the melted activation solder and to remove surface dirt and the passivation layer on the insulation surface for carrying out the dual activation effect of activating the activation solder and the insulation surface. Thus, the present invention can relatively increase the application property of the substrate having the circuit patterns.

To achieve the above object, the present invention provides a method for forming circuit patterns on a surface of a substrate, which comprises the following steps of: providing and pre-heating a substrate having an insulation surface on one side thereof; providing an activation connection device for oscillating and painting an activation solder onto the pre-heated insulation surface to heat and melt the activation solder on the insulation surface; applying ultrasonic waves to the melted activation solder by the activation connection device, so as to activate the activation solder and the insulation surface by the ultrasonic waves; and moving the activation connection device, so as to form a circuit pattern on the insulation surface by the activation solder.

In one embodiment of the present invention, the substrate is a heat-dissipation substrate; the heat-dissipation substrate is selected from a ceramic substrate, an anodized aluminum substrate, an anodized magnesium substrate, an anodized titanium substrate, a glass substrate, a zirconia (ZrO₂) substrate, an aluminum nitride (AlN) substrate or a silicon substrate; and the insulation surface is selected from ceramic material of oxide, carbide or nitride.

In one embodiment of the present invention, the other side of the heat-dissipation substrate has a plurality of heat-dissipation fins.

In one embodiment of the present invention, the activation solder is selected from tin-based alloy, indium-based alloy or other welding alloy, and added with 0.01-2.0 wt % of rare earth metal (Re), wherein the rare earth metal can be Scandium (Sc), Yttrium (Y) and/or Lanthanide, wherein the Lanthanide includes lanthanum (La), cerium (Ce), Praseodymium (Pr), Neodymium (Nd), Promethium (Pm), Samarium (Sm), Europium (Eu), Gadolinium (Gd), Terbium (Tb), Dysprosium (Dy), Holmium (Ho), Erbium (Er), Thulium (Tm), Ytterbium (Yb) or Lutecium (Lu). However, in actual use of industry, the rare earth metal is generally a mixture of several types of elements, wherein the common mixture of the rare earth metal is consist of lanthanum (La), cerium (Ce), Praseodymium (Pr), Neodymium (Nd), Samarium (Sm) and trace portion of iron (Fe), phosphorus (P), sulfur (S) or silicon (Si).

In one embodiment of the present invention, the tin-based alloy, bismuth-based alloy or the indium-based alloy is doped with 6 wt % or less of at least one activation component which can be selected from 4 wt % or less of Titanium (Ti), Vanadium (V), Magnesium (Mg), Lithium (Li), Zirconium (Zr), Hafnium (Hf) or the combination thereof; and the remaining weight is rare earth metal which can be Scandium element (Sc), Yttrium (Y), Lanthanide or the combination thereof.

In one embodiment of the present invention, the thickness of the circuit patterns is ranged between 5 and 45 micrometers (μm).

In one embodiment of the present invention, after the step of forming the circuit patterns, further comprising steps of: stacking an insulation layer on the circuit patterns; heating the insulation layer; oscillating and painting another activation solder having a low melting point onto the pre-heated insulation layer by the activation connection device, to heat and melt the activation solder having the low melting point; applying ultrasonic waves to the melted activation solder having the low melting point by the activation connection device, so as to activate the activation solder having the low melting point and the insulation layer by the ultrasonic waves; and moving the activation connection device, so as to form another circuit pattern on the insulation layer by the activation solder having the low melting point.

In one embodiment of the present invention, after the step of forming the circuit patterns, further comprising steps of: mounting at least one electronic component on the circuit patterns, wherein the circuit patterns includes at least two electrical connection pads for being electrically connected to at least two leads of the electronic component; and the circuit patterns includes at least one thermally conductive pad for being in contact with at least one heat-dissipation pad of the electronic component. The electronic component can be selected from a resistor, a capacitor, an integrated circuit (IC) chip, a light emitting diode (LED) chip, a switch, a laser element, a heat-dissipation element or other electronic elements.

In one embodiment of the present invention, the activation connection device further comprises a multi-axis motion device to move the activation connection device above the insulation surface with a 3-dimensional profile, so as to form the circuit patterns with the 3-dimensional profile.

### DESCRIPTION OF THE DRAWINGS

FIG. 1 is a schematic view of a method for forming circuit patterns on a surface of a substrate according to a preferred embodiment of the present invention, wherein the insulation surface is activated by ultrasonic waves and the activation solder is melted by heating;

FIG. 1A is a partially enlarged view of FIG. 1;

FIG. 2 is a schematic view of the method for forming circuit patterns on the surface of the substrate according to the preferred embodiment of the present invention, wherein an activation connection device is moved to form a circuit pattern;

FIG. 3 is a schematic view of the method for forming circuit patterns on the surface of the substrate according to the preferred embodiment of the present invention, wherein the substrate is mounted with electronic components; and

FIG. 4 is a metallurgical microscopic photograph of a connection cross section of a circuit pattern formed on a glass substrate by using an activation solder of Sn3.5Ag0.5Cu4Ti(Re) according to the preferred embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings.

The present invention provides a method for forming circuit patterns on a surface of a substrate, wherein the method firstly pre-heats an insulation surface of a substrate; then directly connects a melted activation solder onto the insulation surface by oscillating and painting the activation solder on the insulation surface; and activates the activation solder and the insulation surface of the substrate by ultrasonic waves, wherein the ultrasonic waves can smoothly weld the activation solder on the insulation surface to form desired circuit patterns which can be mounted with electronic components in the following process. In the present invention, a heat-dissipation substrate 1 is exemplified to describe the preferred embodiment of the present invention hereinafter.

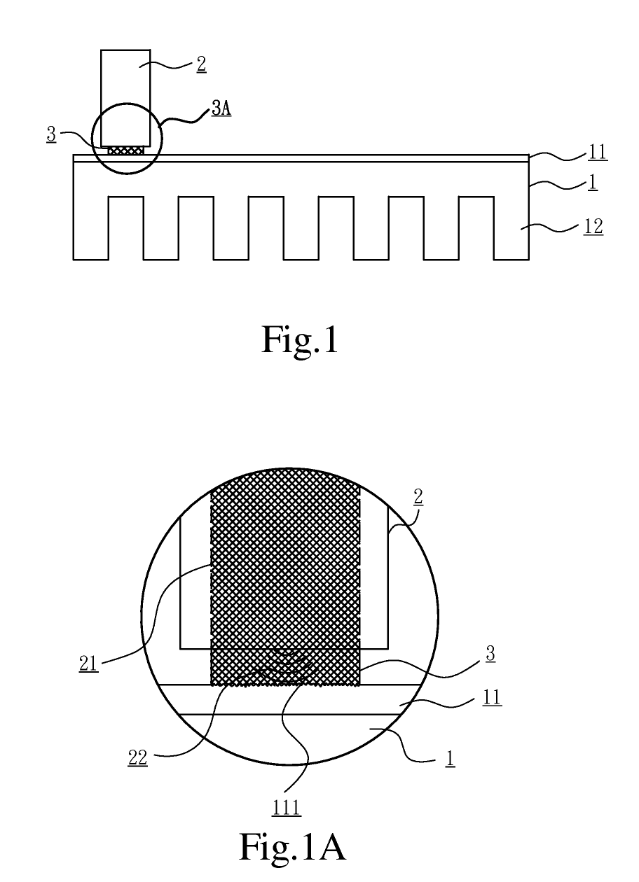

Referring now to FIGS. 1, 2 and 3, a method for forming circuit patterns on a surface of a substrate according to a preferred embodiment of the present invention is illustrated and comprises the following steps of: providing and pre-heating a heat-dissipation substrate 1 having an insulation surface 11 on one side thereof; providing an activation connection device 2 for oscillating and painting an activation solder 3 onto the pre-heated insulation surface 11 to heat and melt the activation solder 3; applying ultrasonic waves 22 to the melted activation solder 3 by the activation connection device 2, so as to activate the activation solder 3 and the insulation surface 11 by the ultrasonic waves 22; and moving the activation connection device 2, so as to form a circuit pattern 30 on the insulation surface 11 by the activation solder 3.

Referring back to FIG. 1, the method for forming circuit patterns on the surface of the substrate according to the preferred embodiment of the present invention is firstly to providing and pre-heating a heat-dissipation substrate 1 having an insulation surface 11 on one side thereof. In the embodiment, the heat-dissipation substrate 1 is exemplified by an anodized aluminum substrate, wherein the insulation surface 11 means an alumina (Al₂O₃) film (i.e. ceramic film) which is formed by anodizing a surface of an aluminum substrate, and the alumina film has an electrical insulation property and a good thermal conductivity. On the other hand, the surface of the aluminum substrate also can be processed by micro-arc oxidation to form the alumina film.

In other embodiments of the present invention, the anodized substrate or micro-arc oxidation substrate can be aluminum (Al) alloy, magnesium (Mg) alloy, titanium (Ti) alloy or tantalum (Ta) alloy. In further another embodiment of the present invention, the heat-dissipation substrate 1 can be wholly a ceramic substrate or a glass substrate, which is originally an insulation material to provide an insulation surface 11. Alternatively, the heat-dissipation substrate 1 can be a zirconia (ZrO₂) substrate or an aluminum nitride (AlN) substrate, which is a substrate made of Al, other metal or ceramic material and has an insulation surface 11 of ZrO₂ or AlN.

Moreover, the other side of the heat-dissipation substrate 1 preferably has a plurality of heat-dissipation fins 12 for increasing the heat-dissipation efficiency, wherein the type of the heat-dissipation fins 12 can be adjusted according to actual product needs, or the heat-dissipation fins 12 can be omitted or be replaced by other heat-dissipation means, such as heat pipes. The heat-dissipation substrate 1 must be pre-heated up to a temperature greater than a predetermined melting point of the activation solder 3 used in the following steps, wherein the melting point thereof may be 100-450° C., without limitation.

Referring to FIGS. 1 and 1A, the method for forming circuit patterns on the surface of the substrate according to the preferred embodiment of the present invention is then to provide an activation connection device 2 for oscillating (i.e. high speed stirring) and painting (i.e. linearly printing) an activation solder 3 onto the pre-heated insulation surface 11 to heat and melt the activation solder 3. In the embodiment, the activation connection device 2 has a feeding channel 21 for supplying a linear solid-state solder wire of one type of the activation solder 3, so as to continuously output the activation solder 3. At this time, the activation solder 3 is in contact with the insulation surface 11 and heated by the pre-heat of the insulation surface 11, so as to be melted. However, the method of supplying the activation solder 3 by the activation connection device 2 can be other ways. For example, the activation connection device 2 can be provided with a pre-heating element therein, wherein the pre-heating element pre-heats, softens and melts the activation solder 3, and then outputs the softened and melted activation solder 3 from the feeding channel 21 or other suitable channel, so as to increase the heated and melted speed of the activation solder 3 after being in contact with the insulation surface 11 and to increase the speed of welding connection there between.

In the present invention, the activation solder 3 is preferably selected from in-based (Sn) alloy, indium-based alloy or other welding alloy, which is added with 0.01-2.0 wt % of rare earth metal (Re). Furthermore, the tin-based alloy, bismuth-based alloy or the indium-based alloy is preferably doped with 6 wt % or less of at least one activation component which can be selected from 4 wt % or less of Titanium (Ti), Vanadium (V), Magnesium (Mg), Lithium (Li), Zirconium (Zr), Hafnium (Hf) or the combination thereof; and the remaining weight is rare earth metal, wherein the rare earth metal can be selected from Scandium element (Sc), Yttrium (Y), Lanthanide or the combination thereof. The activation component is advantageous to increase the following connection property.

For more details, the activation component has affinity toward oxygen, carbon or nitrogen (such as oxygen, carbon or nitrogen of various ceramic film including alumina, carbides or nitrides), wherein a chemical reaction will cause the insulation surface 11 of ceramic material to generate surface decomposition, so as to form a reaction connection layer 111. The reaction connection layer 111 contains reaction products which are composite of metal of the activation component and ceramic material and has microstructures similar to metal, so that it is advantageous to efficiently wet the surface of the reaction connection layer 111 by the melted metal which is then filled into pores or other dead spaces of the insulation surface 11. Thus, the liquid-state melted activation solder 3 can directly wet and connect onto the cleared insulation surface 11. As a result, only if the present invention controls parameters of the pre-heating temperature of the insulation surface 11 and the painting speed of the activation solder 3, the purpose of simply and rapidly connecting the activation solder 3 onto the insulation surface 11 can be carried out, the process can be easily controlled, and the welding connection property will be enhanced.

Referring to FIGS. 1 and 1A, the method for forming circuit patterns on the surface of the substrate according to the preferred embodiment of the present invention is then to apply ultrasonic waves 22 to the melted activation solder 3 by the activation connection device 2, so as to activate the activation solder 3 and the insulation surface 11 by the ultrasonic waves 22. In the present invention, the activation connection device 2 can be used to oscillate and paint the activation solder 3, and simultaneously generate the ultrasonic waves 22 with suitable frequency, wherein the frequency and processing time of the ultrasonic waves 22 can be adjusted according to the type of the activation solder 3, the desired painting thickness or other parameters, so that the frequency and processing time thereof are not limited in the present invention.

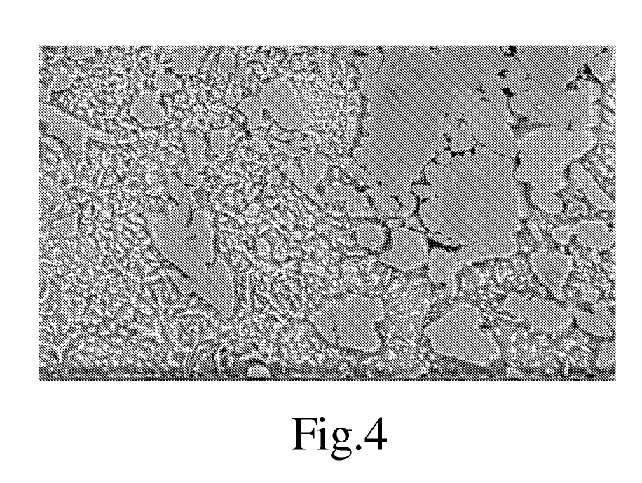

In this step, when the melted activation solder 3 is in contact with the insulation surface 11, the activation connection device 2 can apply the power of the ultrasonic waves 22 to the melted activation solder 3, wherein the wave power of the ultrasonic waves 22 enters the melted activation solder 3, so that the ultrasonic waves can oscillate and break the surface oxidation film of the activation solder 3 to thus expose the metal solder and activation component of the activation solder 3. Meanwhile, a reaction connection layer 111 is formed between the activation component of the activation solder 3 and the insulation surface 11. Referring now to FIG. 4, a metallurgical microscopic photograph of a connection cross section of a circuit pattern formed on a glass substrate by using an activation solder 3 of Sn3.5Ag0.5Cu4Ti(Re) (i.e. contains 3.5% of Ag, 0.5% of Cu, 4% of Ti, trace rare earth metal Re, and balance of Sn) according to the preferred embodiment of the present invention is illustrated.

In addition, the ultrasonic waves 22 can provide a friction type cleaning function toward the solid state surface of the insulation surface 11 through oscillating particles of extremely hard intermetallic compounds (IMGs) of the activation solder 3, so as to efficiently remove surface dirt and a passivation layer on the insulation surface 11. After the insulation surface 11 is cleaned by the ultrasonic waves 22, the reaction connection layer 111 is formed, wherein the reaction connection layer 111 is also called an activating connection interface. At the same time, the ultrasonic waves 22 can remove air bubbles in the melted activation solder 3 to prevent the activation solder 3 from having bubbles therein after welding. Besides, the activation solder 3 can give additional kinetic energy to the melted activation solder 3, so that the melted activation solder 3 can be filled into pores or other dead spaces of the insulation surface 11. Thus, the liquid state melted activation solder 3 can be directly and rigidly connected to the cleaned insulation surface 11 by welding.

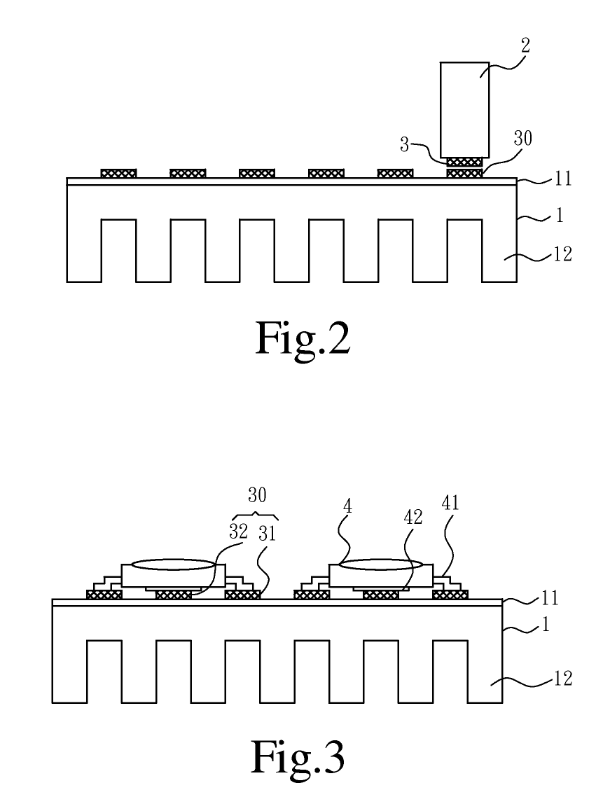

Referring to FIG. 2, the method for forming circuit patterns on the surface of the substrate according to the preferred embodiment of the present invention is then to move the activation connection device 2, so as to form a circuit pattern 30 on the insulation surface 11 by the activation solder 3. In this step, during moving the activation connection device 2 along a predetermined pathway, the melted activation solder 3 is gradually welded and connected on suitable position of the insulation surface 11. Thus, after the activation solder 3 is cooled and solidified, the circuit pattern 30 can be formed, wherein the thickness of the circuit pattern 30 is preferably ranged from 5 to 45 micrometers (μm), while the pattern shape of the circuit pattern 30 is designed according to needs of the following to-be-mounted electronic components 4.

If necessary, the present invention can execute an electroless plating process to the activation solder 3 of the circuit pattern 30, in order to suitably add the thickness of the circuit pattern 30. In this case, the metal used by the electroless plating process is preferably copper (Cu), nickel (Ni), gold (Au), silver (Ag), tin (Sn) or the composite layer thereof. The electroless plating process is used to form a metal plating layer which is advantageous to increase the welding property and rust resistance of the circuit pattern 30 during executing the surface mounting technology (SMT). In addition, if each of two sides of the heat-dissipation substrate 1 has the insulation surface 11 (i.e. the heat-dissipation substrate 1 has no heat-dissipation fins), the present invention can use the foregoing steps to form one circuit pattern 30 onto each insulation surface 11 of two sides of the heat-dissipation substrate 1.

Alternatively, after forming one circuit pattern 30 on the insulation surface 11 of the heat-dissipation substrate 1, the present invention can pre-fabricate another ceramic material (such as ceramic material of oxide, carbide or nitride) and stack the ceramic material on the circuit pattern 30, and use the foregoing steps to form and laminate another circuit pattern 30, so as to form a multi-layer circuit pattern having two or more circuit layers.

For more details, the manufacturing method of the multi-layer circuit pattern is executed after forming the first circuit pattern 30, and the manufacturing method further comprises the following steps of: stacking an insulation layer on the circuit patterns 30; heating the insulation layer; oscillating and painting another activation solder having a low melting point onto the pre-heated insulation layer by the activation connection device 2, to heat and melt the activation solder having the low melting point; applying ultrasonic waves to the melted activation solder having the low melting point by the activation connection device 2, so as to activate the activation solder having the low melting point and the insulation layer by the ultrasonic waves; and moving the activation connection device 2, so as to form another circuit pattern (layer) on the insulation layer by the activation solder having the low melting point. It should be noted that the activation solders for fabricating the multi-layer circuit pattern can be selected from different activation solders with several different melting points (from higher to lower), each of which is used to form one circuit pattern (layer) on one insulation layer by similar steps in turn.

Meanwhile, the activation solders can be used to form through holes or via to electrically connect adjacent circuit patterns (layers) on adjacent insulation layers in a vertical direction, so as to construct a multi-layer circuit board. In other words, each circuit pattern (layer) of the multi-layer circuit board can directly use the activation solders as filler material to form conductive through holes or via, instead of electroplated or electroless plated conductive through holes or via of a traditional multi-layer circuit board. Thus, the process efficiency of the multi-layer circuit board can be enhanced.

Furthermore, in certain products, the insulation surface 11 of the heat-dissipation substrate 1 may be a 3-dimensional non-planar surface, such as hemi-spherical surface. The present invention also can use the foregoing steps to form one layer of circuit pattern, or two or more layer of multi-layer circuit patterns. In this case, the activation connection device 2 further comprises a multi-axis motion device (not-shown) to move the activation connection device 2 above the insulation surface 11 with a 3-dimensional profile, so as to form the circuit patterns 30 with the 3-dimensional profile. This application is also one of various possible embodiments of the present invention.

Then, referring now to FIG. 3, after finishing the foregoing steps, selectively further comprising another step of: mounting at least one electronic component 4 on the circuit patterns 30, wherein the electronic component 4 is preferably a light emitting diode (LED) chip. In one embodiment, each of the electronic components 4 includes at least two leads 41 and at least one heat-dissipation pad 42, wherein the leads are used to electrically connect to an external power, and the heat-dissipation pad 42 is used to transfer waste heat generated by the electronic component 4 outward. Moreover, the trace line of the circuit patterns 30 includes at least two electrical connection pads 31 and at least one thermally conductive pad 32, wherein the electrical connection pads 31 is used to weld and electrically connect to the leads 41 of the electronic component 4 by the SMT technology, so that the electric power of the external power can be guided to the leads 41. Meanwhile, the thermally conductive pad 32 is used to be in contact with the heat-dissipation pad 42 of the electronic component 4 through the SMT technology or thermally conductive adhesive, so that the heat-dissipation pad 42 can transfer waste heat of the electronic component 4 outward to the heat-dissipation substrate 1, followed by exhausting the waste heat by the heat-dissipation fins 12 of the heat-dissipation substrate 1.

As described above, in comparison with the surface circuit layer of the traditional heat-dissipation substrate which may be easily peeled off due to material deterioration to affect the adhesion strength of the surface circuit layer and the heat dissipation effect of the LEDs, the present invention as shown in FIGS. 1 to 3 firstly pre-heats the insulation surface 11 of the substrate 1; then directly heats and connects a melted activation solder 3 onto the insulation surface 11 after oscillating and painting the activation solder 3 on the insulation surface 11; and activates the insulation surface 11 and the activation solder 3 by ultrasonic waves 22, wherein the ultrasonic waves 22 can break the surface oxidation film of the activation solder 3, while the energy of the ultrasonic waves can efficiently remove surface dirt and a passivation layer on the insulation surface 11 through particles of extremely hard intermetallic compounds (IMGs) of the activation solder 3, in order to carry out the dual activation effect of activating the activation solder 3 and the insulation surface 11. Thus, after the insulation surface 11 is formed with the reaction connection layer 111, the present invention can relatively increase the connection property of wetting and connecting the activation solder 3 onto the insulation surface 11, and thus it is advantageous to enhance the connection strength and process efficiency of the circuit patterns 30.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A method for forming circuit patterns on a surface of a substrate, comprising steps of:
providing and pre-heating a substrate having an insulation surface on one side thereof;
providing an activation connection device for oscillating and painting an activation solder onto the pre-heated insulation surface to heat and melt the activation solder;
applying ultrasonic waves to the melted activation solder by the activation connection device, so as to activate the activation solder and the insulation surface by the ultrasonic waves; and
moving the activation connection device, so as to form a circuit pattern on the insulation surface by the activation solder.

2. The method for forming circuit patterns on a surface of a substrate according to claim 1, wherein the substrate is a heat-dissipation substrate.

3. The method for forming circuit patterns on a surface of a substrate according to claim 2, wherein the heat-dissipation substrate is selected from a ceramic substrate, an anodized aluminum substrate, an anodized magnesium substrate, an anodized titanium substrate, a glass substrate, a zirconia substrate or an aluminum nitride substrate.

4. The method for forming circuit patterns on a surface of a substrate according to claim 2, wherein the insulation surface is selected from ceramic material of oxide, carbide or nitride.

5. The method for forming circuit patterns on a surface of a substrate according to claim 1, wherein after the step of forming the circuit patterns, further comprising steps of:
stacking an insulation layer on the circuit patterns;
heating the insulation layer;
oscillating and painting another activation solder having a low melting point onto the pre-heated insulation layer by the activation connection device, to heat and melt the activation solder having the low melting point;
applying ultrasonic waves to the melted activation solder having the low melting point by the activation connection device, so as to activate the activation solder having the low melting point and the insulation layer by the ultrasonic waves; and
moving the activation connection device, so as to form another circuit pattern on the insulation layer by the activation solder having the low melting point.

6. The method for forming circuit patterns on a surface of a substrate according to claim 1, wherein the activation solder is selected from tin-based alloy, bismuth-based alloy or indium-based alloy, and added with 0.01-2.0 wt % of rare earth metal (Re) which is scandium (Sc), yttrium (Y) and/or lanthanide.

7. The method for forming circuit patterns on a surface of a substrate according to claim 6, wherein the tin-based alloy, the bismuth-based alloy or the indium-based alloy is doped with 6 wt % or less of at least one activation component which is selected from 4 wt % or less of titanium (Ti), vanadium (V), magnesium (Mg), zirconium (Zr), hafnium (Hf) or the combination thereof; and the remaining weight is rare earth metal which is scandium element (Sc), yttrium (Y), lanthanide or the combination thereof.

8. The method for forming circuit patterns on a surface of a substrate according to claim 1, wherein the activation connection device further comprises a multi-axis motion device to move the activation connection device above the insulation surface with a 3-dimensional profile, so as to form the circuit patterns with the 3-dimensional profile.

9. The method for forming circuit patterns on a surface of a substrate according to claim 1, wherein after the step of forming the circuit patterns, further comprising steps of: mounting at least one electronic component on the circuit patterns.

10. The method for forming circuit patterns on a surface of a substrate according to claim 9, wherein the circuit patterns includes: at least two electrical connection pads for being electrically connected to at least two leads of the electronic component; and the circuit patterns includes at least one thermally conductive pad for being in contact with at least one heat-dissipation pad of the electronic component.

11. The method for forming circuit patterns on a surface of a substrate according to claim 9, wherein the electronic component is selected from a resistor, a capacitor, an integrated circuit (IC) chip, a light emitting diode (LED) chip, a switch, a laser element or a heat-dissipation element.

12. The method for forming circuit patterns on a surface of a substrate according to claim 1, wherein the thickness of the circuit patterns is ranged between 5 and 45 μm.

13. The method for forming circuit patterns on a surface of a substrate according to claim 1, wherein the other side of the heat-dissipation substrate has a plurality of heat-dissipation fins.
